(19) United States
(12) Patent Application Publication
(10) Pub. No.: US 2007/0084583 A1
(43) Pub. Date: Apr. 19, 2007

(54) Structure for connecting radiating fins

(76) Inventor: Wen-Hsing Pan, Tucheng City (TW)

Correspondence Address: BIRCH STEWART KOLASCH & BIRCH, PO BOX 747, FALLS CHURCH, VA, 22040-0747, US

(21) Appl. No.: 11/249,416

(22) Filed: Oct. 14, 2005

(51) Int. Cl. H05K 7/20

(52) U.S. Cl. 165/80.3; 165/185; 361/704

(57) ABSTRACT

A structure for connecting radiating fins includes a plurality of parallelly arranged and vertically spaced radiating fins and at least one connector. Each of the radiating fins is provided on at least one outer edge with at least one receiving section, so that at least one group of aligned receiving sections is formed. The connector is lengthwise provided with a plurality of spaced engaging sections corresponding to the number of and the space between the radiating fins, and is positioned in the group of aligned receiving sections to thereby extend across and hold the parallelly arranged and vertically spaced radiating fins in place.

### FIELD OF THE INVENTION

The present invention relates to a structure for connecting radiating fins, and more particularly to a structure for connecting a plurality of parallelly spaced and stacked radiating fins to one another.

### BACKGROUND OF THE INVENTION

For a heat-producing electronic element, such as a CPU, to constantly operate at a normal working temperature, it is necessary to effectively carry away the high amount of heat produced by the electronic element during the operation thereof. Typically, a radiator is attached to the electronic element to radiate heat produced by the electronic element. Currently, there are radiators made of extruded or cast aluminum available for use. These types of radiators are pre-fabricated to have a very limited radiating surface that could not be adjusted according to the temperature of heat produced by the electronic element. To overcome the disadvantages of the extruded or cast aluminum radiators, there is developed a radiator consisting of a plurality of pre-formed metal sheets having a high thermal conductivity. Different numbers of such metal sheets may be parallelly stacked and spaced to adjust or increase the effective heat radiating surface of the radiator.

Taiwanese Patent publication No. M245501 discloses a Heat Sink with Stacked Fins, which includes a base, a plurality of parallel fins vertically mounted on a surface of the base, and two locking members. Each of the fins has an edge that is bent and then extends by a distance to form a flange bent, at where the fin is attached to the surface of the base; and an opposite edge that is bent at two opposite ends to form two bent tabs. A through hole is provided on each bent tab at a proper position. Each of the two locking members is provided at two ends with a pair of vertically downward extended stop tabs, in an inner side of which there is provided a projection each. The locking member has one side being formed into a plurality of vertically downward extended insert tabs, which may be inserted into a space between two adjacent fins for the projections at two end of the locking member to engage with the through holes on the fins.

It is known that the space left between two adjacent fins serves as a path for airflow to carry away the heat from the fins, so as to achieve the purpose of dissipating heat. In the heat sink disclosed in Taiwanese Patent publication No. M245501, when the insert tabs on the locking members are inserted into the spaces between two adjacent fins, they also block the spaces to interfere with the free flow of air in the spaces. Therefore, heat is not easily carried away from the fins by the air. Moreover, the locking members have complicate structure and must be manufactured with more material to increase the manufacturing cost thereof.

It is therefore tried by the inventor to develop a structure for connecting radiating fins to eliminate the drawbacks in the conventional radiators.

### SUMMARY OF THE INVENTION

A primary object of the present invention is to provide at least one connector that is provided with a plurality of engaging sections to engage with receiving sections provided on a plurality of radiating fins, so as to keep the radiating fins in a parallelly arranged and vertically spaced position.

Another object of the present invention is to provide a connector that is able to connect a plurality of radiating fins to one another without interfering with the free flow of air between two adjacent radiating fins.

A further object of the present invention is to provide a structure for connecting radiating fins, which is structurally simple and can be easily assembled and operated to enable reduced manufacturing cost thereof.

To achieve the above and other objects, the structure for connecting radiating fins according to the present invention includes a plurality of parallelly arranged and vertically spaced radiating fins and at least one connector. Each of the radiating fins is provided on at least one outer edge with at least one receiving section, a top of which is flush with the outer edge of the radiating fin. The connector is in the form of an elongate strip and is lengthwise provided with a plurality of spaced engaging sections corresponding to the number of and the space between the radiating fins for engaging with the receiving sections on the radiating fins.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a structure for connecting radiating fins according to a first embodiment of the present invention;

FIG. 2 is an assembled view of FIG. 1;

FIG. 3 is an exploded perspective view of a structure for connecting radiating fins according to a second embodiment of the present invention;

FIG. 4 is an assembled view of FIG. 3;

FIG. 5 is a perspective view showing the connected radiating fins of FIG. 2 is mounted to a base;

FIG. 6 is a perspective view showing the connected radiating fins of FIG. 4 is mounted to a base;

FIG. 7 is an exploded perspective view of a structure for connecting radiating fins according to a third embodiment of the present invention being mounted on a base;

FIG. 8 is an assembled view of FIG. 7;

FIG. 9 is a fragmentary and enlarged exploded perspective view of a structure for connecting radiating fins according to a fourth embodiment of the present invention;

FIG. 10 is an assembled view of FIG. 9;

FIG. 11 is a fragmentary and enlarged exploded perspective view of a structure for connecting radiating fins according to a fifth embodiment of the present invention;

FIG. 12 is an assembled view of FIG. 11;

FIG. 13 is a fragmentary perspective view showing another embodiment of the connector included in the first, the second, and the third embodiment of the present invention; and

FIG. 14 is a fragmentary perspective view showing another embodiment of the connector included in the fourth and the fifth embodiment of the present invention.

### DETAILED DESCRIPTION OF THE PREFERRED EMBODIMENTS

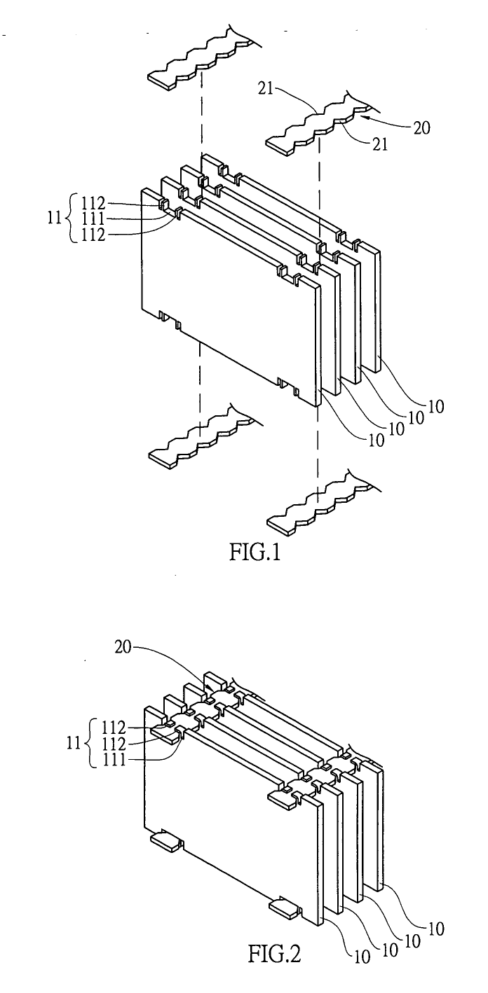

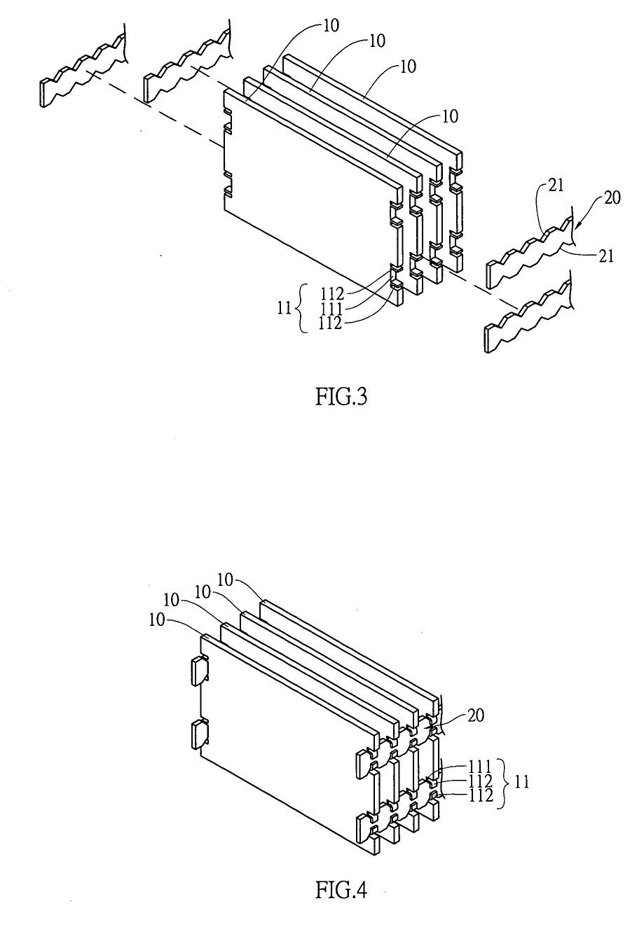

Please refer to FIGS. 1 and 2 that are exploded and assembled perspective views, respectively, of a structure for connecting radiating fins according to a first embodiment of the present invention. As shown, the structure in the first embodiment of the present invention includes a plurality of radiating fins 10, and a plurality of connectors 20. The radiating fins 10 are parallelly arranged and vertically spaced, and are symmetrically provided near two ends of upper and lower edges with four receiving sections 11 each. That is, there are total four groups of aligned receiving sections 11 formed on the parallelly arranged and vertically spaced radiating fins 10. Each of the receiving sections 11 includes a recess 111 and two spaced pins 112 extended from a bottom of the recess 111 to flush with the upper or the lower edge of the radiating fin 10.

The connectors 20 are in the form of an elongate strip each. In the first embodiment of the present invention, there are four connectors 20 corresponding to the four groups of aligned receiving sections 11 provided on the radiating fins 10. Each of the connectors 20 is lengthwise provided with a plurality of engaging sections 21 corresponding to the number of and the space between the radiating fins 10. Each of the engaging sections 21 in the first embodiment of the present invention includes two notches symmetrically provided at two opposite sides of the connector 20.

To connect the parallelly arranged radiating fins 10 by the connectors 20, first position the four connectors 20 in the four groups of aligned receiving sections 11 one by one, such that each notched engaging section 21 on the connectors 20 is seated in one recess 111 between the two spaced pins 112. Then, bend the two pins 112 toward the connector 20 to hold or clamp the connector 20 between them, so that the connector 20 is extended across the parallelly arranged radiating fins 10 to connect to each of the radiating fins 10 at the receiving sections 11. After all the four connectors 20 have been connected to the receiving sections 11 of the radiating fins 10, the parallel radiating fins 10 are supported by the connectors 20 to vertically space from one another at a fixed distance.

FIGS. 3 and 4 are exploded and assembled perspective views, respectively, of a structure for connecting radiating fins according to a second embodiment of the present invention. The second embodiment is structurally similar to the first embodiment, except that the four groups of aligned receiving sections 11 are provided near two ends of two opposite lateral edges of the radiating fins 10. After all the connectors 20 are positioned in the four groups of receiving sections 11 one by one with the notched engaging sections 21 seated in the recesses 111 and held thereto by the pins 112, the radiating fins 10 could be connected together while parallelly and vertically spaced from one another.

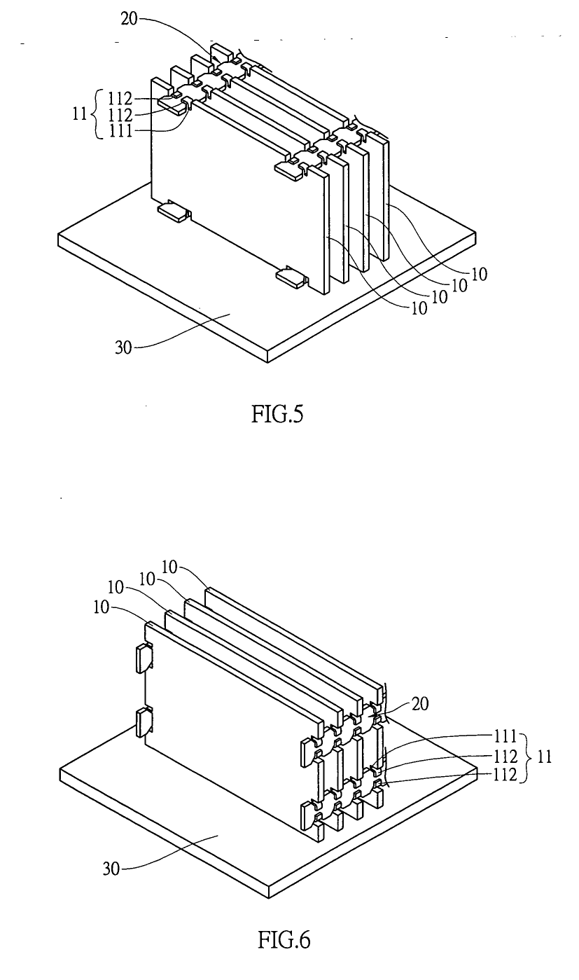

FIGS. 5 and 6 shows the radiating fins 10 connected together using the first and the second embodiment of the present invention, respectively, may be mounted on a base 30 through bonding or grooves (not shown) preformed on the base 30 corresponding to the radiating fins 10.

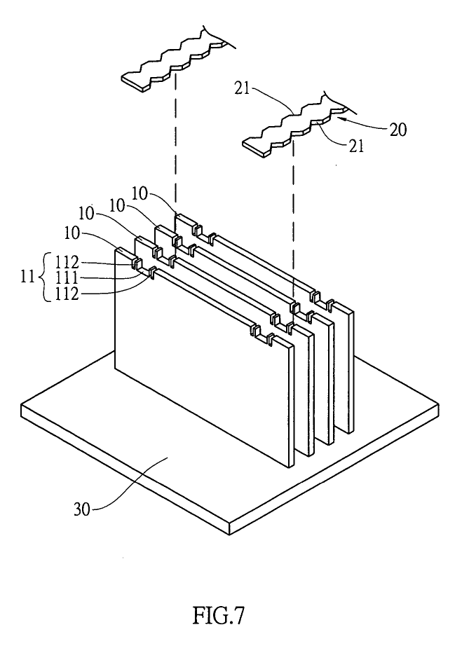

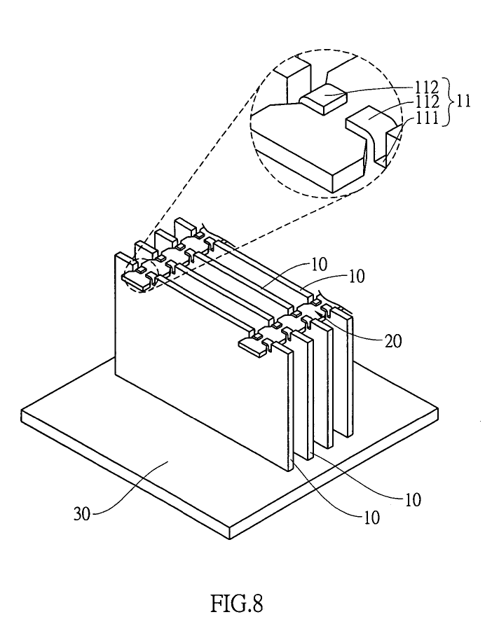

FIGS. 7 and 8 are exploded and assembled perspective views, respectively, of a structure for connecting radiating fins according to a third embodiment of the present invention. The third embodiment is structurally similar to the first and the second embodiment, except that the receiving sections 11 are only provided near two ends of the upper edges of the radiating fins 10, so that there are only two groups of aligned receiving sections 11 and two connectors 20. As in the first and the second embodiment, the radiating fins 10 connected together using the third embodiment of the present invention may be connected at a lower side to a base 30.

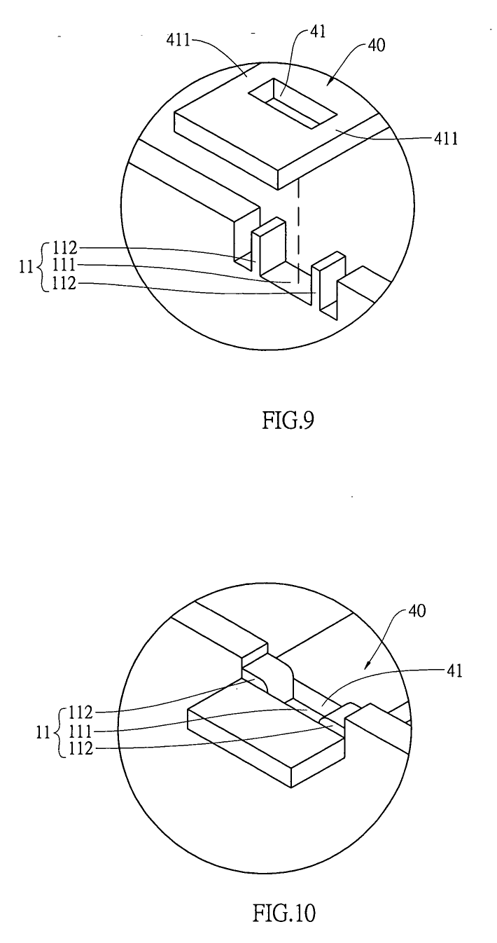

Please refer to FIGS. 9 and 10 that are fragmentary exploded and assembled perspective views, respectively, of a structure for connecting radiating fins according to a fourth embodiment of the present invention. In the fourth embodiment, the structure of the present invention includes a plurality of radiating fins 10 similar to those in the first, the second, and the third embodiment, and a plurality of connectors 40 corresponding to the number of groups of receiving sections 11 provided on the radiating fins 10. Each of the connectors 40 is in the form of an elongate strip having two straight lateral edges, and is lengthwise provided with a plurality of spaced engaging sections 41 corresponding to the number of and the space between the radiating fins 10. In the fourth embodiment of the present invention, each of the engaging sections 41 includes a through opening 41. A portion 411 of the connector 40 is left between each lateral end of the through opening 41 and a corresponding lateral edge of the connector 40, such that the connector 40 may be positioned in each group of aligned receiving sections 11 with the two pins 112 in each of the receiving sections 11 extended through one corresponding opening 41. Thereafter, the two pins 112 may be bent laterally outward to overlap the portions 411 and thereby hold the connector 40 to the receiving section 11.

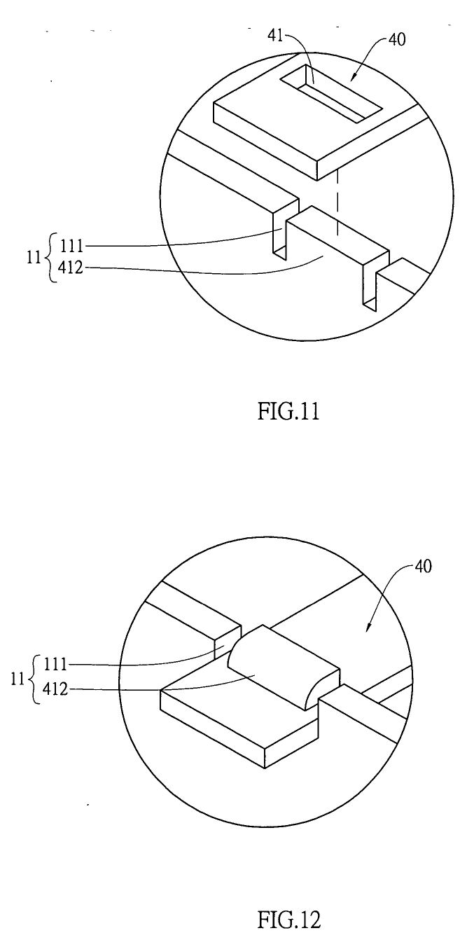

FIGS. 11 and 12 are fragmentary exploded and assembled perspective views, respectively, of a structure for connecting radiating fins according to a fifth embodiment of the present invention. In the fifth embodiment, the structure of the present invention includes a plurality of radiating fins 10 and a plurality of connectors 40. The radiating fins 10 in the fifth embodiment are similar to those in the first, the second, and the third embodiment, except that each of the receiving sections 11 thereof includes a recess 111 and a centered dam 412 extended from a bottom of the recess 111 toward a corresponding outer edge of the radiating fin 10. The connectors 40 are similar to those in the fourth embodiment, and the dam 412 has dimensions corresponding to that of the through opening 41. When the connector 40 is positioned in each group of aligned receiving sections 11, the dam 412 in each of the receiving sections 11 is extended through one corresponding opening 41. Thereafter, the dam 112 may be bent to overlap the connector 40 and thereby hold the connector 40 to the receiving section 11.

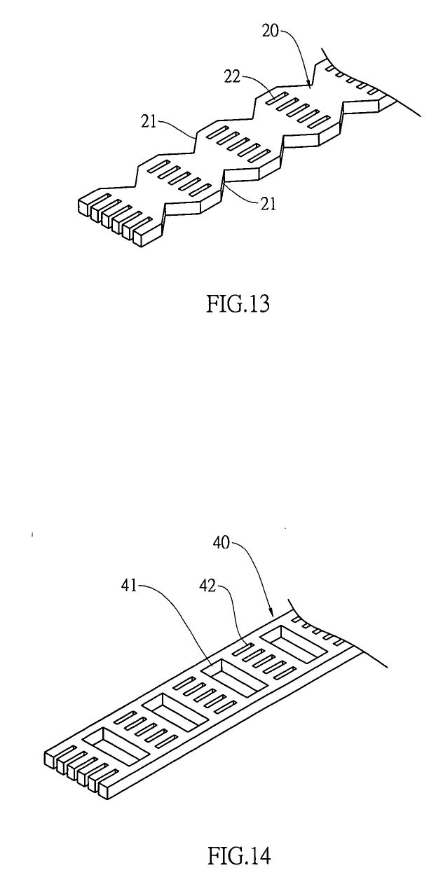

In another embodiment of the connectors 20, at least one vent 22 is provided in every area on the connectors 20 between two adjacent notched engaging sections 21, as shown in FIG. 13, so that air between any two adjacent radiating fins 10 below the connectors 20 is allowed to freely flow through the vents 22 without being interfered by the connectors 20.

Similarly, in another embodiment of the connectors 40, at least one vent 42 is provided in every area on the connectors 40 between two adjacent through openings 41, as shown in FIG. 14, so that air between any two adjacent radiating fins 10 below the connectors 40 is allowed to freely flow through the vents 42 without being interfered by the connectors 40.

In implementing the present invention, a bonding agent may be applied over contact surfaces between the receiving sections 11 and the engaging sections 21 or 41 to ensure an enhanced connection between the radiating fins 10 and the connectors 20, 40.

With the present invention, a plurality of radiating fins 10 may be connected by a predetermined number of independent connectors 20, 40 to be parallel with and vertically spaced from one another. The connectors 20, 40 of the present invention have simple structure to enable easy connection of the connectors to the receiving sections 11 on the radiating fins 10, making the present invention easy to produce at increased productivity. Moreover, the connectors 20, 40 of the present invention are elongate strips connected to the radiating fins 10 without being inserting into the spaces between the radiating fins 10 to interfere with the outward flowing of air between the radiating fins 10. And, the vents 22, 42 provided on the connectors 20, 40 further facilitate free airflow through any two adjacent radiating fins 10. All these arrangements of the present invention advantageously upgrade the radiating efficiency of the radiating fins 10.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A structure for connecting radiating fins, comprising:
a plurality of parallelly arranged and vertically spaced radiating fins, each of said radiating fins being provided on at least one outer edge with at least one receiving section, so that at least one group of aligned receiving sections is formed; said receiving sections having a top flush with said outer edges of said radiating fins; and
at least one connector in the form of an elongate strip and being lengthwise provided with a plurality of spaced engaging sections corresponding to the number of and the space between said radiating fins; and
each of said connectors being positioned in one said group of aligned receiving sections to thereby extend across and hold said parallelly arranged and vertically spaced radiating fins in place.

2. The structure for connecting radiating fins as claimed in claim 1, wherein each of said receiving sections includes a recess and two spaced pins, and said two spaced pins being extended from a bottom of said recess to flush with the outer edge of said radiating fin.

3. The structure for connecting radiating fins as claimed in claim 1, wherein each of said receiving sections includes a recess and at least one dam, and said at least one dam being centered in said recess to extend from a bottom of said recess to the outer edge of said radiating fin.

4. The structure for connecting radiating fins as claimed in claim 1, wherein each of said engaging sections includes two notches symmetrically provided at two opposite sides of said connector.

5. The structure for connecting radiating fins as claimed in claim 2, wherein each of said engaging sections includes two notches symmetrically provided at two opposite sides of said connector.

6. The structure for connecting radiating fins as claimed in claim 1, wherein each of said engaging sections includes a through opening, and a portion of said connector is left between each lateral end of said through opening and a corresponding lateral edge of said connector.

7. The structure for connecting radiating fins as claimed in claim 3, wherein each of said engaging sections includes a through opening, and a portion of said connector is left between each lateral end of said through opening and a corresponding lateral edge of said connector.

8. The structure for connecting radiating fins as claimed in claim 1, wherein said a plurality of radiating fins are connected at one side to a base.

9. The structure for connecting radiating fins as claimed in claim 1, wherein each of said connector is provided in every area between two adjacent engaging sections with at least one vent.

10. The structure for connecting radiating fins as claimed in claim 1, wherein a bonding agent is applied over contact surfaces between said receiving sections and said engaging sections.
